(19) United States
(12) Patent Application Publication
(10) Pub. No.: US 2023/0042271 A1
(43) Pub. Date: Feb. 9, 2023

(54) SYSTEM, DEVICES AND/OR PROCESSES FOR DESIGNING NEURAL NETWORK PROCESSING DEVICES

(71) Applicant: Arm Limited, Cambridge (GB)

(72) Inventors: Igor Fedorov, Ashland, MA (US); Ramon Matas Navarro, Newburyport, MA (US); Chuteng Zhou, Somerville, MA (US); Hokchhay Tann, Burlington, MA (US); Paul Nicholas Whatmough, Cambridge, MA (US); Matthew Mattina, Boylston, MA (US)

(21) Appl. No.: 17/394,048

(22) Filed: Aug. 4, 2021

(51) Int. Cl. G06F 30/20; G06N 3/063

(52) U.S. Cl. CPC G06F 30/20; G06N 3/063

(57) ABSTRACT

Example methods, apparatuses, and/or articles of manufacture are disclosed that may be implemented, in whole or in part, using one or more computing devices to select options for decisions in connection with design features of a computing device. In a particular implementation, design options for two or more design decisions of neural network processing device may be selected based, at least in part, on combination of function values that are computed based, at least in part, on a tensor expressing sample neural network weights.

### BACKGROUND

### 1. Field

The present disclosure relates generally to computer generation of designs for neural network processing devices.

### 2. Information

Neural Networks have become a fundamental building block in machine-learning and/or artificial intelligence systems. A neural network may be constructed according to multiple different design parameters such as, for example, network depth, layer width, weight bitwidth, approaches to pruning, just to provide a few example design parameters that may affect the behavior of a particular neural network processing architecture. Particular design choices for such design parameters may be selected based, at least in part, on particular performance and/or cost objectives.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1 is a graph illustrating a portion of a process for selection of options for multiple design decisions for a neural network processing architecture, according to an embodiment;

FIGS. 2A, 2B and 2C are graphs illustrating alternative approaches to selecting options for a plurality of decisions for design of a neural network processing architecture, according to an embodiment;

FIG. 2D is a schematic diagram of a system to determine measurements for use in predicting an operational latency for a design of a computing device according to an embodiment;

FIG. 3 is a flow diagram of a process to determine selections for design decisions for a design of a computing device, according to an embodiment; and

FIG. 4 is a schematic block diagram of an example computing system in accordance with an implementation.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

References throughout this specification to one implementation, an implementation, one embodiment, an embodiment, and/or the like means that a particular feature, structure, characteristic, and/or the like described in relation to a particular implementation and/or embodiment is included in at least one implementation and/or embodiment of claimed subject matter. Thus, appearances of such phrases, for example, in various places throughout this specification are not necessarily intended to refer to the same implementation and/or embodiment or to any one particular implementation and/or embodiment. Furthermore, it is to be understood that particular features, structures, characteristics, and/or the like described are capable of being combined in various ways in one or more implementations and/or embodiments and, therefore, are within intended claim scope. In general, of course, as has always been the case for the specification of a patent application, these and other issues have a potential to vary in a particular context of usage. In other words, throughout the disclosure, particular context of description and/or usage provides helpful guidance regarding reasonable inferences to be drawn; however, likewise, “in this context” in general without further qualification refers at least to the context of the present patent application.

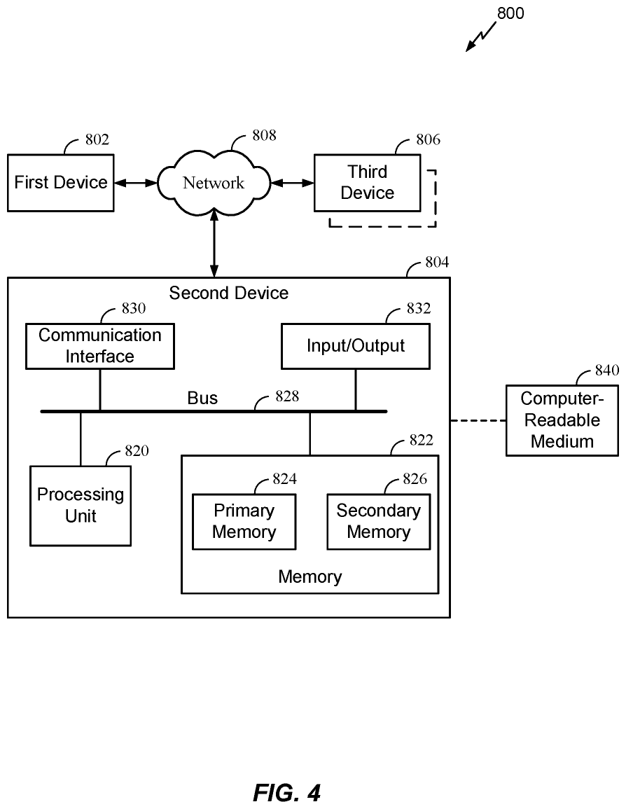

According to an embodiment, a neural network may comprise a graph comprising nodes to model neurons in a brain. In this context, a “neural network” as referred to herein means an architecture of a processing device defined and/or represented by a graph including nodes to represent neurons that process input signals to generate output signals, and edges connecting the nodes to represent to represent input and/or output signal paths between and/or among the artificial neurons represented by the graph. In particular implementations, a neural network may comprise a biological neural network, made up of real biological neurons, or an artificial neural network, made up of artificial neurons, for solving artificial intelligence (AI) problems, for example. In an implementation, such an artificial neural network may be implemented on one or more computing devices such as computing devices shown in FIG. 4. In a particular implementation, weights associated with edges to represent input and/or output paths may reflect gains to be applied and/or whether an associated connection between connected nodes is to be excitatory (e.g., weight with a positive value) or inhibitory connections (e.g., weight with negative value). In an example implementation, a neuron may apply a weight to input signals, and sum weighted input signals to generate a linear combination.

Edges in a neural network connecting nodes may model synapses capable of transmitting signals (e.g., represented by real number values) between neurons. Receiving such a signal at a node in a neural network, the node may perform some computation to generate an output signal (e.g., to be provided to another node in the neural network connected by an edge) based, at least in part, on one or more weights and/or numerical coefficients associated with the node and/or edges providing the output signal. In a particular implementation, such weights and/or numerical coefficients may be adjusted and/or updated as learning progresses. For example, such a weight may increase or decrease a strength of an output signal. In an implementation, transmission of an output signal from a node in a neural network may be inhibited if a strength of the output signal does not exceed a threshold value.

According to an embodiment, a neural network may be structured in layers such that a node in a particular neural network layer may receive output signals from one or more nodes in a previous layer in the neural network, and provide an output signal to one or more nodes in a subsequent layer in the neural network. One specific class of layered neural networks may comprise a convolutional neural network (CNN) or space invariant artificial neural networks (SIANN) that enable deep learning. Such CNNs and/or SIANNs may be based on a shared-weight architecture of a convolution kernels that shift over input features and provide translation equivariant responses. Such CNNs and/or SIANNs may be applied to image and/or video recognition, recommender systems, image classification, image segmentation, medical image analysis, natural language processing, brain-computer interfaces, financial time series, just to provide a few examples.

In particular implementations, neural networks may enable improved results in a wide range of tasks including image recognition or speech recognition, just to provide a couple of example applications. In terms of computing resources, neural networks may occupy large amounts of memory for model storage and consume millions of operations per second in real-time execution. Given a particular neural network architecture, a model may be compressed to yield significant memory and compute savings. Such techniques to yield memory and compute savings may include, for example, pruning, weight quantization, and activation quantization.

As pointed out above, a design of a neural network may be optimized for a particular performance and/or cost objective based, at least, in part on selection of options for decisions of particular design parameters such as, for example, network depth, layer width, weight bitwidth and approaches to pruning. In one embodiment, such selected options for design parameters may be defined solely by a human design for a particular purpose. Alternatively, such choices for design parameters may be determined in an automated fashion such as by machine-learning.

According to an embodiment, design of an efficient and effective neural network architecture may entail substantial human effort and time to develop. Through experimentation, human experts have devised several useful neural network structures such as, for example, attention and residual connection. Given the virtually infinite possible design choices of a neural network architecture, however, manual search for optimal computing architectures may become unfeasible. In another embodiment, an automated neural architecture search (NAS) may enable a more rapid approach to arrive at a neural network architecture that approaches optimality.

In particular implementations, a NAS approach may apply an evolutionary algorithm (EA) and/or reinforcement learning (RL) to design neural network architectures automatically. In both RL-based and EA-based approaches, searching procedures may require validation of accuracy of numerous architecture candidates, which may be computationally expensive. For example, an RL-based method may utilize validation accuracy as a reward to optimize an architecture generator. An EA-based method may leverage validation accuracy to decide whether a model is to be removed from a population. In particular implementations, these approaches may employ use of a large amount of computational resources, which may be inefficient and unaffordable.

According to an embodiment, design parameters affecting performance of a neural network may include, for example, layer width/number of channels, weight bitwidth, activation bitwidth, operator type, network connectivity, network depth, weight sparsity level or activation resolution. It should be understood, however, that these are merely examples of design parameters that may affect performance of a neural network, and that claimed subject matter is not limited in this respect. While some NAS techniques may be effective in optimizing a neural network design over one or two different design parameters, effectiveness of such NAS techniques may diminish in attempts to optimize a neural network design over three or more such design parameters, for example.

Briefly, implementations of particular embodiments are directed to a process of selecting from among options for features of a neural network comprising: computing for each of a plurality of design options of each of a plurality of design decisions for at least one layer of a neural network, a function value based, at least in part, on an expression of sample weights applicable to nodes and/or edges in the neural network and a coefficient associated with the design option; and determining an objective function based, at least in part, on a combination of computed function values associated with the design options of the design parameters. By computing function values associated with particular design options of a design parameter based, at least in part on sample weights applicable to nodes and/or edges and coefficients associated with the particular design parameters, a neural network design may be more effectively optimized over multiple design parameters.

In particular implementations, a process to select from among available candidate options for a decision regarding a feature of a neural network processing architecture may be guided, at least in part, by computed gradient functions. According to an embodiment, such a gradient function f (x, θ, π) may be determined according to expression (1) as follows:

$$f ( x , θ , π ) = {\sum }_{k = 1}^{K} z [ k ] {f}^{k} ( x , {θ}^{k} ) , z = [ \begin{matrix}z [ 1 ] \\ … \\ z [ K ]\end{matrix} ] , \qquad ( 1 )$$

where:

x is an activation input;

θ is a feature/design decision; θ^{k} is a k^{th} option for feature/design decision θ;

z[k] is a coefficient and/or selection value to represent a selection of option θ^{k} for feature/design decision θ;

π is an array of deterministic numerical values corresponding to z[k] for k=1, . . . K to represent associated preferences for selection of options θ^{k} for k=1, . . . , K; and

f^{k} is a transformation associated with option θ^{k} for feature/design decision θ.

According to an embodiment, values for π may be categorically distributed for a particular associated design decision. Subject to such a categorical distribution, individual values for π may be tuned to make more desirable options for an associated design decision more likely to be selected. For example, higher values in an array π may correspond with design options for a particular design decision.

In a particular implementation, an optimal selection of a particular θ^{k}* for a particular design decision may occur according to expression (2) as follows:

$${k}^{*} = {arg max}_{k} π [ k ] , f ( x , θ ) = {f}^{{k}^{*}} ( x , {θ}^{{k}^{*}} ) \qquad ( 2 )$$

In the particular implementation described above with reference to expressions (1) and (2), a single design decision for a single network layer may be optimized over multiple candidate options available for selection. According to an embodiment, features of a neural network design may be optimized over multiple design decisions (e.g., over multiple neural network layers and/or over multiple different features among one or more neural network layers). For example, a loss function may be used to determine an optimal selection of options \hat{Z} over multiple neural network layers and/or over multiple different features for design according to expression (3) as follows:

$$\hat{Θ} , \hat{\prod } = {arg min}_{Θ , Π} {E}_{Z , Data} [ L ( Θ , Z , Data ) ] , \qquad ( 3 )$$

where:
Data is a signal to express a parameter/observation set (e.g., from which activation inputs may be derived);
Θ represents feature/design decisions in a neural network;
Z may comprise an array to represent selections of options for feature/design decisions set forth in Θ(e.g., Z={z_{d}}_{d=1}^{D});
Π is an array of deterministic values corresponding to selections of Z to represent associated preferences for selection of options for feature/design decisions set forth in Θ (e.g., ={z_{d}}_{d=1}^{D}); and
L(Θ, Z, Data) is a predetermined loss function.

According to an embodiment, values in Π may be configured and/or organized to include deterministic values representing preferences for selection of design decisions d=1, . . . , D. In a particular implementation, such deterministic values in Π to represent preferences for options for a single particular design decision d may be categorically distributed.

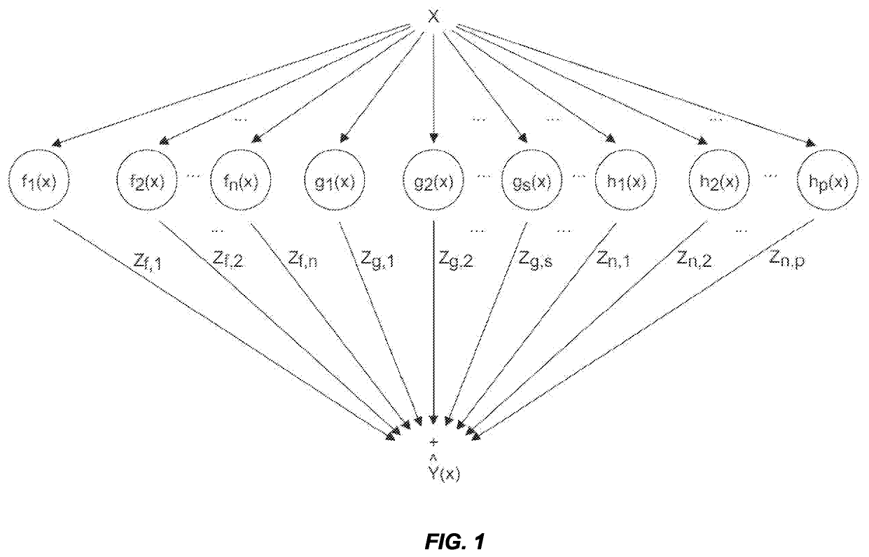

FIG. 1 is a graph illustrating a portion of a process for selection of options for multiple decisions for a neural network architecture, according to an embodiment. In a particular implementation of expression (3), a loss function for selection of options for multiple decisions for a neural network architecture according to the process of FIG. 1 may be provided in expression (4) as follows:

L(Θ, Z, Data)=Σᵢ₌₁^{N}∥yᵢ−ŷ(xᵢ)∥₂², (4)

where:

ŷ(xᵢ)=z_{f,1}f₁(xᵢ)+z_{f,2}f₂(xᵢ)+ . . . +z_{f,n}fₙ(xᵢ)+z_{g,1}g₁(xᵢ)+z_{g,2}g₂(xᵢ)+ . . . +z_{g,s}gₛ(xᵢ)+ . . . +z_{h,1}h₁(xᵢ)+z_{h,2}h₂(xᵢ)+ . . . +z_{h,p}hₚ(xᵢ);
xᵢ is a tensor for an iteration i based, at least in part, on parameter/observation set Data;
yᵢ is an observation function for an iteration i based, at least in part, on parameter/observation set Data (e.g., labels and/or ground truth observations);
f₁, f₂, . . . , fₙ are transformations associated with options θ^{f,1}, θ^{f,2}, . . . , θ^{f,n}, respectively, for feature/design decision θ^{f} (e.g., θ^{f,1}, θ^{f,2}, . . . , θ^{f,n} ∈ Θ);
g₁, g₂, . . . , gₛ are transformations associated with options θ^{g,1}, θ^{g,2}, . . . , θ^{g,s}, respectively, for feature/design decision θ^{g} (e.g., θ^{g,1}, θ^{g,2}, . . . , θ^{g,s} ∈ Θ);
h₁, h₂, . . . , hₚ are transformations associated with options θ^{h,1}, θ^{h,2}, . . . , θ^{h,p}, respectively, for feature/design decision θ^{h} (e.g., θ^{h,1}, θ^{h,2}, . . . , θ^{h,p} ∈ Θ);
z_{f,1}, z_{f,2}, . . . , z_{f,n} are coefficients and/or selection values to represent selection of options θ^{f,1}, θ^{f,2}, . . . , θ^{f,n}, respectively, for feature/design decision θ^{f};
z_{g,1}, z_{g,2}, . . . , z_{g,s} are coefficients and/or selection values to represent selection of options θ^{g,1}, θ^{g,2}, . . . , θ^{g,s}, respectively, for feature/design decision θ^{g}; and
z_{h,1}, z_{h,2}, . . . , z_{h,p} are coefficients and/or selection values to represent selection of options θ^{h,1}, θ^{h,2}, . . . , θ^{h,p}, respectively, for feature/design decision θ^{h}.

In particular implementations, tensor xᵢ may comprise any one of several parameters and/or activation inputs such as, for example, neural network weights (e.g., to be associated with edges and/or nodes) and/or feature maps that are to be derived, at least in part, from parameter/observation set expressed by Data. As such, tensor xᵢ may comprise multi-dimensional array comprising neural network weights to be applied to neural network nodes and/or edges in one or more neural network layers. Such feature maps in tensor xᵢ may comprise, for example, output values for one or more nodes in a neural network that are configured to form a “filter” to assist in feature extraction, classification and/or detection. According to an embodiment, tensor xᵢ may be defined for a sequence of iterations i=1, 2, . . . , N in the execution of a neural network. For example, tensor xᵢ may define activation inputs, input values and/or states to be applied to one or elements of the neural network for an iteration i. In a particular implementation, values for tensor xᵢ for a particular iteration k(xₖ) may be determined based, at least in part, on tensors x₁, x₂, . . . , xₖ₋₁ for iterations preceding iteration k.

According to an embodiment, values for observation function yᵢ may comprise an expected and/or idealized value. For example, observation function yᵢ may comprise and/or be derived from expected filter output values for one or more nodes of a neural network such as, for example, extraction of particular features, classification inferences and/or detections based on activation inputs expressed in Data and obtained independently of execution of the neural network. It should be understood, however, that this is merely an example of how values of for observation function yᵢ may be determined, and claimed subject matter is not limited in this respect. As pointed out above, values for z_{f,1}, Z_{f,2}, . . . , z_{f,n} may behave according to an associated categorical distribution. Likewise, values for z_{f,1}, z_{f,2}, . . . , z_{g,m} may behave according to another associated categorical distribution, and values for z_{h,1}, z_{h,2}, . . . , z_{h,p} may behave according to yet another associated categorical distribution. In a particular implementation, in execution of individual iterations of ∥yᵢ−ŷ(xᵢ)∥ in expression (4), values for z_{f1}, z_{f2}, . . . , z_{f,n}, z_{g,1}, z_{g,2}, . . . , z_{g,s} and z_{h,1}, z_{h,2}, . . . , z_{h,p} may be randomized according to associated categorical distributions to enable a Monte Carlo analysis for determining values for \hat{Z} in expression (3). For example, randomized values for Z (e.g., as represented by Π) may be generated in a corresponding sequence for iterations i=1, 2, . . . , N according to a Markov chain Monte Carlo (MCMC) sampling where Πᵢ may be computed based on Πᵢ₋₁.

According to an embodiment, N may be sufficiently large to enable values for Π_{N} to converge so that each of Π_{f,N}, Π_{g,N} and Π_{h,N} include a single dominant value (e.g., ≈1.0) and other values that approach zero. Selections for \hat{Z} may then be determined according to expressions (5), (6) and (7) as follows:

$${\hat{Z}}_{f} = {arg max}_{1 , 2 , … , n} {\prod }_{f , N} \qquad ( 5 )$$

$${\hat{Z}}_{g} = {arg max}_{1 , 2 , … , s} {\prod }_{g , N} \qquad ( 6 )$$

$${\hat{Z}}_{h} = {arg max}_{1 , 2 , … , p} {\prod }_{h , N} , \qquad ( 7 )$$

where:
Π_{f,N} comprises converged MCMC samples corresponding to z_{f,1}, z_{f,2}, . . . , z_{f,n};
Π_{g,N} comprises converged MCMC samples corresponding to z_{g,1}, z_{g,2}, . . . , z_{g,s}; and
Π_{h,N} comprises converged MCMC samples corresponding to z_{h,1}, z_{h,2}, . . . , z_{h,p}; and
\hat{Z}_{f}, \hat{Z}_{g}, . . . , \hat{Z}ₕ ∈ \hat{Z}.

According to an embodiment, expression (3) may be somewhat modified to an optimal selection of options \hat{Z} subject to one or more constraints. Such a constraint may comprise, for example, an availability of flash memory storage capacity, denoted as e*, for a given size of a neural network in bytes, denoted as e(Z). Such a size of a neural network may be determined, for example, based on a size of weights to be stored (e.g., “file size” if such weights are maintained in a file). Such a size of a neural network may also account for a cost for storage of executable code in addition to storage of weights. Such a cost may be incorporated into e(Z) by including an offset to represent a Flash memory cost of running any neural network on a device. Other such constraints may comprise power consumption constraints, processor throughput/latency constraints and/or physical size constraints. It should be understood, however, that these are merely examples of constraints that may be applied in the selection of candidate options for design decisions, and claimed subject matter is not limited in this respect. According to an embodiment. Here, expression (3) may be somewhat modified to reflect optimization subject to such constraints according to expression (8) as follows:

$${\hat{Z}}_{{E}_{Z} [ e ( Z ) ] \leq {e}^{*}} = {argmin}_{Θ , \{ \prod : {E}_{Z} [ e ( Z ) ] \leq {e}^{*} \}} [ L ( Θ , Z , Data ) ] \qquad ( 8 )$$

In a specific implementation, such an optimization subject to constraints in expression (8) may be carried out according to expression (9) as follows:

$${\hat{Z}}_{{E}_{Z} [ e ( Z ) ] \leq {e}^{*}} = {argmin}_{Θ , \prod } [ L ( Θ , Z , Data ) ] + μ {E}_{Z} [ \vert e ( Z ) - {e}^{*} \vert ] , \qquad ( 9 )$$

where μ is a weighting parameter.

As may be observed, a second term of expression (9) may comprise determination of an expectation of a “distance” between e(Z) and e*. As such, a selected configuration may satisfy a constraint that e(Z) is to be centered about e*, and that a variance of a complexity measure may be relatively small. This may provide an advantage in discouraging solutions μ having no clear dominant or “winner” component and in discouraging solutions μ which are uniform and have two or more highly dominant options. According to an embodiment, meeting a constraint set forth in expression (8) may be enabled by solving expression (9) in the limit as μ→∞. In an alternative embodiment, expression (3) may be adapted to incorporate an constraint e* according to expression (10) as follows:

$$\hat{Z} = {argmin}_{Θ , \prod } {E}_{Z , Data} [ L ( Θ , Z , Data ) ] + λ \times {{E}_{Z} [ e ( Z ) - {e}^{*} ]}^{2} . \qquad ( 10 )$$

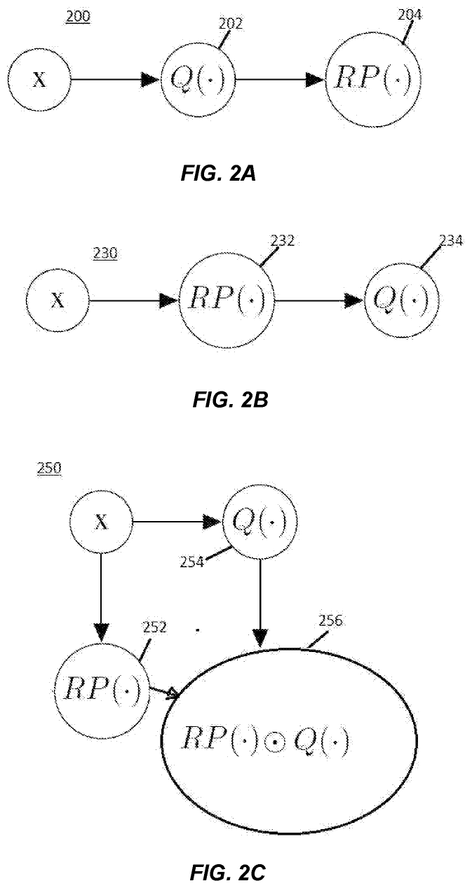

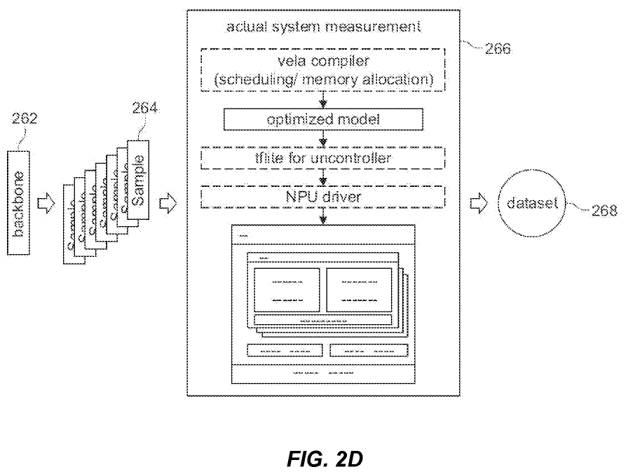

Expression (9) and/or (10) may also incorporate a constraint directed to latency of operation where e* represents a maximum latency and E_{Z}[e(Z)] represents a predicted latency for a selection Z. According to an embodiment, E_{Z}[e(Z)] may be determined based, at least in part, on measured cost values obtained from samples of an operational hardware computing platform and/or through a simulation. As shown in the particular example implementation of FIG. 2D, for example, a computing backbone 262 may be executed and/or modeled (e.g., to perform one or more particular computing tasks), and sample values 264 relating to execution latency (e.g., latency of certain computing components to perform certain computing tasks under particular conditions) may be obtained. Sample values 264 may then be processed and/or conditioned at a measurement system 266 to provide a dataset 268 comprising measured latency cost values associated with particular design options as pairs <design options, measured latency cost value>. Measured latency cost values collected in dataset 268 may be applied to a sparse array representing design options for a neural network.

According to an embodiment, Z may be modeled as a deterministic function Z=q(G, Π) where G is a random variable. \hat{Z}_{E}_{_{Z}}_{[e(Z)]≤e*} may then be determined using a gradient estimator based, at least in part, on expression (11) as follows:

$$\frac{\partial {E}_{Z , Data} [ L ( Θ , Z , Data ) ]}{\partial \prod } = \frac{\partial {E}_{Z , Data} [ L ( Θ , q ( G , \prod ) , Data ) ]}{\partial \prod } \qquad ( 11 )$$

In particular implementation, a value for the right-hand portion of expression (11) may be approximated using a Monte-Carlo sampling according to expression (12) as follows:

$$\frac{\partial {E}_{Z , Data} [ L ( Θ , q ( G , \prod ) , Data ) ]}{\partial \prod } \approx \frac{1}{S} {\sum }_{s = 1}^{S} \frac{\partial {E}_{Z , Data} [ L ( Θ , q ( {G}^{s} , \prod ) , Data ) ]}{\partial \prod } , \qquad ( 12 )$$

where G^{s} is an s^{th} sample of G.

According to an embodiment, a value for Z=q(G, Π) may be approximated according to expression (13) as follows:

$$q ( G , π ) = softmax ( \frac{log π [ k ] + g [ k ]}{λ} ) , \qquad ( 13 )$$

where g˜Gumbel(0,1) and λ is a softmax temperature parameter.

According to an embodiment, use of expression (13) may decouple a source of randomness for Z from Π. This may thus enable a Monte-Carlo style backpropagation for determination of Z according to expression (12), for example.

According to an embodiment, an approximation of a gradient estimator shown in expression (12) may be determined from S multiple iterations. As may be observed, a variance in a gradient estimator shown in expression (12) is proportional to S⁻². As such, a variance in such a gradient estimator computed in multiple iterations S may be reduced as compared to a variance of a gradient estimator computed in a single iteration where S=1. Additionally, computing of a gradient estimator in multiple iterations S may enable amortization of a cost in constructing a computational model, which may yield faster execution of an optimization algorithm.

As pointed out above, design decisions θ for features of a neural network may be directed to one or more of several features including, for example, channel width, number of neurons for a fully connected layer, bitwidth for weights, random sparsity rate for weights, neural network depth, neural network connectivity, operator type, activation bitwidth, just to provide a few examples. For a design decision directed to a channel width of a neural network layer, for example, related transformation may be set forth according to expression (14) as follows:

f(x, θ)=BN(conv(x, θ)), (14)

where:

cony is a convolution function;

θ represents options for channel width; and
BN is a batch normalization operation.

Here, a specific implementation of expression (1) for channel width may be provided in a gradient function as set forth in expression (16) as follows:

f^{k}(x, θ)=BN(conv(x, θ))⊙ m^{k} (15)

f(x, θ, π)=BN(conv(x, θ))⊙ Σₖ₌₁^{K} z[k]m^{k}, (16)

where:
⊙ is a Hadmard product or elementwise product;
m^{k} is a binary, channel-wise mask, m^{k} ∈ [symbol] ^{D}^{ₒᵤₜ}; and
Dₒᵤₜ is a number of output channels.

As may be observed, in the particular implementation of expression (16), complexity associated with computing expression (16) may be relatively unchanged with changes in a number of channel width options since a convolution operation may be performed only once.

For a design decision directed to a quantization (e.g., to be applied to weights and/or activation inputs/outputs), for example, a related transformation may be set forth to quantize a tensor x using a uniform quantizer according to expression (17) as follows:

$${Q}^{b} ( x , {r}_{{min}^{k}} , {r}_{max}^{k} , b ) = d \times round ( \frac{clip ( x , {r}_{min} , {r}_{max} )}{d} ) , \qquad ( 17 )$$

where:

rₘᵢₙ and rₘₐₓ are the minimum and maximum of tensor x, respectively;

rₘᵢₙ_{^{k}} is a quantization range minimum;

rₘₐₓ^{k} is quantization range maximum;

b is a quantization bitwidth;

round rounds values of a tensor to a nearest integer;

clip limits tensor values to specified minimum and maximum values; and

$$d = \frac{{r}_{max} - {r}_{min}}{{2}^{b - 1}} .$$

According to an embodiment, selection of a particular bitwidth b may entail a tradeoff of model complexity (e.g., with smaller b) for a given minimum task performance (e.g., with larger b). A specific implementation of expression (1) for quantization may be provided in a gradient function set forth in expression (18) as follows:

f(x, Ω, π)=Σₖ₌₁^{K} z[k]Q^{b}^{^{k}} (x, rₘᵢₙ_{^{k}}, rₘₐₓ^{k}), (18)

where:

Ω={rₘᵢₙ_{^{k}}, rₘₐₓ^{k}}ₖ₌₁^{K}.

In this context, a neural network may be pruned by setting individual parameters (e.g., weights) to zero, thereby making the neural network sparse. This may lower a number of parameters in a model maintaining a neural network architecture intact. Alternatively, a neural network may be pruned by removing entire nodes from the neural network. This would make a neural network smaller while avoiding significant impacts to accuracy. According to an embodiment, random pruning comprises pruning of a neural network in which every layer in the neural network is to be pruned by the same or similar amount. For a design decision directed to a level of random pruning, for example, a portion of tensor x may be set to zero. Such setting of a portion of tensor x to zero may entail application of random pruning with a non-zero ratio ρ to a weight tensor θ that may be set forth according to expression (17) as follows:

RP^{ρ}(θ)=m^{ρ} ⊙ θ, (19)

where:

∥m^{ρ}∥₀└m^{ρ}×|θ|┘; and
m^{ρ} is a binary mask.

A specific implementation of expression (1) for selection of a non-zero ratio to prune a given weight tensor may be provided in a gradient function set forth in expression (18) as follows:

f(x, θ, π)=x ⊙ Σₖ₌₁^{K} z[k]m^{ρ}^{^{k}} (20)

As pointed out above, in some embodiments a neural network may be optimized over multiple selections of options \hat{Z} for associated multiple design decisions according to expression (3). FIGS. 2A, 2B and 2C are graphs illustrating alternative approaches to optimize selections of design options for a quantization decision (θ^{Q}) and design options for a random pruning decision (θ^{RP}). FIG. 2A is a graph 200 illustrating a two-stage optimization in which a selection of options for quantization \hat{Z}^{Q} is determined at a first stage 202, followed by a determination of a selection of options for random pruning \hat{Z}^{RP} at a second stage 204 subject to selection of options \hat{Z}^{Q} determined at first stage 202. Here, selection of options for quantization \hat{Z}^{Q} and options for random pruning \hat{Z}^{RP} may be determined according to expressions (19) and (20) as follows:

$${\hat{Z}}^{Q} = {argmin}_{{θ}^{Q} , {π}^{Q}} {E}_{{Z}^{Q} , {Data}_{Q}} [ L ( {θ}^{Q} , {Z}^{Q} , {Data}_{Q} ) ] \qquad ( 21 )$$

$${\hat{Z}}^{RP} = {argmin}_{{θ}^{RP} , {π}^{RP}} {E}_{{Z}^{RP} , {Data}_{RP}} [ L ( {θ}^{RP} , {Z}^{RP} , {Data}_{RP} \vert {\hat{Z}}^{Q} ) ] , \qquad ( 22 )$$

where:
θ^{Q} is a set of options for feature/design decisions for quantization;
θ^{RP} is a set of options for feature/design decisions for random pruning;
Data_{Q} is a signal expressing activation inputs for determining selections \hat{Z}^{Q};
Data_{RP} is a signal expressing activation inputs for determining selections \hat{Z}^{RP};
π^{Q} is an array of deterministic values corresponding to values for Z^{Q}; and
π^{RP} is an array of deterministic values corresponding to values for Z^{RP}.

FIG. 2B is a graph 230 illustrating a two-stage optimization in which a selection of options for random pruning \hat{Z}^{RP} is determined at a first stage 232, followed by a determination of a selection of options for quantization \hat{Z}^{Q} at a second stage 234 subject to selection of options \hat{Z}^{RP} determined at first stage 232. Here, selection of options for quantization \hat{Z}^{Q} and options for random pruning \hat{Z}^{RP} may be determined according to expressions (23) and (24) as follows:

$${\hat{Z}}^{RP} = {argmin}_{{θ}^{RP} , {π}^{RP}} {E}_{{Z}^{RP} , {Data}_{RP}} [ L ( {θ}^{RP} , {Z}^{RP} , {Data}_{RP} ) ] \qquad ( 23 )$$

$${\hat{Z}}^{Q} = {argmin}_{{θ}^{Q} , {π}^{Q}} {E}_{{Z}^{Q} , {Data}_{Q}} [ L ( {θ}^{Q} , {Z}^{Q} , {Data}_{Q} \vert {\hat{Z}}^{RP} ) ] . \qquad ( 24 )$$

FIG. 2C is a graph 250 illustrating a process by which optimization 252 for selection of options for random pruning \hat{Z}^{RP} is determined concurrently with optimization 254 for selection of options for quantization \hat{Z}^{Q}. While graph 250 illustrates a process for concurrent optimization of selection of options for two design decisions (for quantization and random pruning), other embodiments may comprise processes for concurrent optimization of selection of three or more design decisions. For example, in a particular implementation of expression (3), selections for three or more design decisions of a neural network may be concurrently optimized. In a particular implementation, optimized selection of channel width, quantization and/or random pruning (e.g., ∈ Θ) for a neural network. Letting f₁, f₂, . . . , fₙ be transformations associated with options for channel width, g₁, g₂, . . . , gₘ be transformations associated with options for quantization and h₁, h₂, . . . , hₚ be transformations associated with options for random pruning, a particular implementation of a loss function if expression (4) may be set forth in expression (25) as follows:

L(⊙, Z, Data)=Σᵢ₌₁^{N} ∥yᵢ−[BN(conv(xᵢ, θ^{f}))⊙ Σₖ₌₁ⁿ z_{f,n}m^{k}+Σₖ₌₁^{s} z_{g,k}Q^{b}^{^{k}}(xᵢ, rₘᵢₙ_{^{k}}, rₘₐₓ^{k})+ . . . +xᵢ ⊙ Σₖ₌₁^{p} z_{h,k}m^{ρ}^{^{k}}]∥₂². (25)

In an embodiment, values for \hat{Z}_{f}, \hat{Z}_{g} and \hat{Z}ₕ (to represent selections for channel width, quantization and random pruning, respectively) may then be determined by applying a gradient estimator according to expression (11) and an MCMC sampling according to expressions (5), (6), (7) and (8).

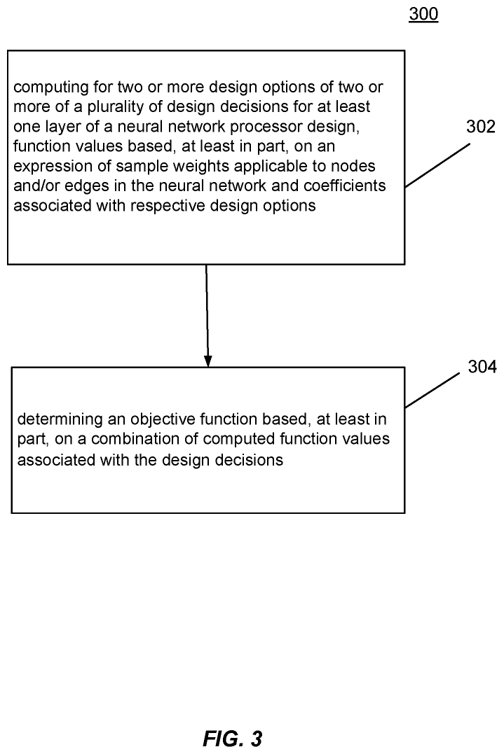

FIG. 3 is a flow diagram of a process 300 for determining features of a neural network design according to an embodiment. In a particular implementation, process 300 may be executed and/or controlled by execution by one or more computing devices of computer-readable instructions stored on a non-transitory memory device. Block 302 comprises computing, for multiple design options of multiple design decisions for at least one layer of a neural network of a processing device, a function value.

In a particular example implementation, block 302 may compute such function values from application of transformations f₁, f₂, . . . , fₙ, g₁, g₂, . . . , gₛ, h₁, h₂, . . . , hₘ to weights associated with edges and/or nodes in the neural network (e.g., as activation inputs provided in tensor x) and coefficients for z_{f,1}, z_{f,2}, . . . , z_{f,n}, z_{g,1}, z_{g,2}, . . . z_{g,s}, z_{h,1}, z_{h,2}, . . . , z_{h,p}, for example, as shown in expression (4) above. It should be understood, however, that this is merely an example of how function values for multiple design options of multiple design decisions may be computed, and that claimed subject matter is not limited in this respect.

According to an embodiment, block 302 may compute functions values associated with two or more of design decisions directed to two or more of network depth, layer width, layer width/number of channels, weight bitwidth, activation bitwidth, operator type, network connectivity of nodes, network depth, weight sparsity level or activation resolution. In a particular implementation, for example, block 302 may compute function values associated with first design decision relating to a bitwidth parameter and least a second design decision relating to a random pruning approach.

Block 304 may comprise determination of an objective function based, at least on function values computed at block 302. Such an objective function may be based, at least in part, on a loss function such as L(Θ, Z, Data) in expression (4) in which such a loss function is determined based, at least in part, on a sum of function values determined in block 302. In an embodiment, function values associated with design options may be computed based, at least in part, on coefficients computed for a previous iteration of computing function values from tensor input values. According to an embodiment, such coefficients may be associated with design options for a particular single design decision, and may be modeled according to a categorical distribution. In an example implementation, an objective function may be computed from multiple iterations of processing of tensor input values where computed coefficients are varied according to an MCMC sampling. For example, a gradient estimator may be applied to iterations of the objective function according to expression (11). Selections of options for design decisions may then be determined according to expressions (5), (6) and/or (7), for example.

According to an embodiment, block 304 may determine an objective function subject to one or more processing constraints such as, for example, an availability of memory, processing throughput and/or latency, power usage, physical size, just to provide a few examples of constraints. For example, such constraints may be incorporated into an objective function according to expression (9).

In the context of the present patent application, the term “connection,” the term “component” and/or similar terms are intended to be physical but are not necessarily always tangible. Whether or not these terms refer to tangible subject matter, thus, may vary in a particular context of usage. As an example, a tangible connection and/or tangible connection path may be made, such as by a tangible, electrical connection, such as an electrically conductive path comprising metal or other conductor, that is able to conduct electrical current between two tangible components. Likewise, a tangible connection path may be at least partially affected and/or controlled, such that, as is typical, a tangible connection path may be open or closed, at times resulting from influence of one or more externally derived signals, such as external currents and/or voltages, such as for an electrical switch. Non-limiting illustrations of an electrical switch include a transistor, a diode, etc. However, a “connection” and/or “component,” in a particular context of usage, likewise, although physical, can also be non-tangible, such as a connection between a client and a server over a network, particularly a wireless network, which generally refers to the ability for the client and server to transmit, receive, and/or exchange communications, as discussed in more detail later.

In a particular context of usage, such as a particular context in which tangible components are being discussed, therefore, the terms “coupled” and “connected” are used in a manner so that the terms are not synonymous. Similar terms may also be used in a manner in which a similar intention is exhibited. Thus, “connected” is used to indicate that two or more tangible components and/or the like, for example, are tangibly in direct physical contact. Thus, using the previous example, two tangible components that are electrically connected are physically connected via a tangible electrical connection, as previously discussed. However, “coupled,” is used to mean that potentially two or more tangible components are tangibly in direct physical contact. Nonetheless, “coupled” is also used to mean that two or more tangible components and/or the like are not necessarily tangibly in direct physical contact, but are able to co-operate, liaise, and/or interact, such as, for example, by being “optically coupled.” Likewise, the term “coupled” is also understood to mean indirectly connected. It is further noted, in the context of the present patent application, since memory, such as a memory component and/or memory states, is intended to be non-transitory, the term physical, at least if used in relation to memory necessarily implies that such memory components and/or memory states, continuing with the example, are tangible.

Unless otherwise indicated, in the context of the present patent application, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, that the particular situation be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated. As an example, if a plot of measurements over a region is produced and implementation of claimed subject matter refers to employing a measurement of slope over the region, but a variety of reasonable and alternative techniques to estimate the slope over that region exist, claimed subject matter is intended to cover those reasonable alternative techniques unless otherwise expressly indicated.

To the extent claimed subject matter is related to one or more particular measurements, such as with regard to physical manifestations capable of being measured physically, such as, without limit, temperature, pressure, voltage, current, electromagnetic radiation, etc., it is believed that claimed subject matter does not fall with the abstract idea judicial exception to statutory subject matter. Rather, it is asserted, that physical measurements are not mental steps and, likewise, are not abstract ideas.

It is noted, nonetheless, that a typical measurement model employed is that one or more measurements may respectively comprise a sum of at least two components. Thus, for a given measurement, for example, one component may comprise a deterministic component, which in an ideal sense, may comprise a physical value (e.g., sought via one or more measurements), often in the form of one or more signals, signal samples and/or states, and one component may comprise a random component, which may have a variety of sources that may be challenging to quantify. At times, for example, lack of measurement precision may affect a given measurement. Thus, for claimed subject matter, a statistical or stochastic model may be used in addition to a deterministic model as an approach to identification and/or prediction regarding one or more measurement values that may relate to claimed subject matter.

For example, a relatively large number of measurements may be collected to better estimate a deterministic component. Likewise, if measurements vary, which may typically occur, it may be that some portion of a variance may be explained as a deterministic component, while some portion of a variance may be explained as a random component. Typically, it is desirable to have stochastic variance associated with measurements be relatively small, if feasible. That is, typically, it may be preferable to be able to account for a reasonable portion of measurement variation in a deterministic manner, rather than a stochastic matter as an aid to identification and/or predictability.

Along these lines, a variety of techniques have come into use so that one or more measurements may be processed to better estimate an underlying deterministic component, as well as to estimate potentially random components. These techniques, of course, may vary with details surrounding a given situation. Typically, however, more complex problems may involve use of more complex techniques. In this regard, as alluded to above, one or more measurements of physical manifestations may be modelled deterministically and/or stochastically. Employing a model permits collected measurements to potentially be identified and/or processed, and/or potentially permits estimation and/or prediction of an underlying deterministic component, for example, with respect to later measurements to be taken. A given estimate may not be a perfect estimate; however, in general, it is expected that on average one or more estimates may better reflect an underlying deterministic component, for example, if random components that may be included in one or more obtained measurements, are considered. Practically speaking, of course, it is desirable to be able to generate, such as through estimation approaches, a physically meaningful model of processes affecting measurements to be taken.

In some situations, however, as indicated, potential influences may be complex. Therefore, seeking to understand appropriate factors to consider may be particularly challenging. In such situations, it is, therefore, not unusual to employ heuristics with respect to generating one or more estimates. Heuristics refers to use of experience related approaches that may reflect realized processes and/or realized results, such as with respect to use of historical measurements, for example. Heuristics, for example, may be employed in situations where more analytical approaches may be overly complex and/or nearly intractable. Thus, regarding claimed subject matter, an innovative feature may include, in an example embodiment, heuristics that may be employed, for example, to estimate and/or predict one or more measurements.

It is further noted that the terms “type” and/or “like,” if used, such as with a feature, structure, characteristic, and/or the like, using “optical” or “electrical” as simple examples, means at least partially of and/or relating to the feature, structure, characteristic, and/or the like in such a way that presence of minor variations, even variations that might otherwise not be considered fully consistent with the feature, structure, characteristic, and/or the like, do not in general prevent the feature, structure, characteristic, and/or the like from being of a “type” and/or being “like,” (such as being an “optical-type” or being “optical-like,” for example) if the minor variations are sufficiently minor so that the feature, structure, characteristic, and/or the like would still be considered to be substantially present with such variations also present. Thus, continuing with this example, the terms optical-type and/or optical-like properties are necessarily intended to include optical properties. Likewise, the terms electrical-type and/or electrical-like properties, as another example, are necessarily intended to include electrical properties. It should be noted that the specification of the present patent application merely provides one or more illustrative examples and claimed subject matter is intended to not be limited to one or more illustrative examples; however, again, as has always been the case with respect to the specification of a patent application, particular context of description and/or usage provides helpful guidance regarding reasonable inferences to be drawn.

The term electronic file and/or the term electronic document are used throughout this document to refer to a set of stored memory states and/or a set of physical signals associated in a manner so as to thereby at least logically form a file (e.g., electronic) and/or an electronic document. That is, it is not meant to implicitly reference a particular syntax, format and/or approach used, for example, with respect to a set of associated memory states and/or a set of associated physical signals. If a particular type of file storage format and/or syntax, for example, is intended, it is referenced expressly. It is further noted an association of memory states, for example, may be in a logical sense and not necessarily in a tangible, physical sense. Thus, although signal and/or state components of a file and/or an electronic document, for example, are to be associated logically, storage thereof, for example, may reside in one or more different places in a tangible, physical memory, in an embodiment.

A Hyper Text Markup Language (“HTML”), for example, may be utilized to specify digital content and/or to specify a format thereof, such as in the form of an electronic file and/or an electronic document, such as a Web page, Web site, etc., for example. An Extensible Markup Language (“XML”) may also be utilized to specify digital content and/or to specify a format thereof, such as in the form of an electronic file and/or an electronic document, such as a Web page, Web site, etc., in an embodiment. Of course, HTML and/or XML are merely examples of “markup” languages, provided as non-limiting illustrations. Furthermore, HTML and/or XML are intended to refer to any version, now known and/or to be later developed, of these languages. Likewise, claimed subject matter are not intended to be limited to examples provided as illustrations, of course.

In the context of the present patent application, the terms “entry,” “electronic entry,” “document,” “electronic document,” “content”, “digital content,” “item,” and/or similar terms are meant to refer to signals and/or states in a physical format, such as a digital signal and/or digital state format, e.g., that may be perceived by a user if displayed, played, tactilely generated, etc. and/or otherwise executed by a device, such as a digital device, including, for example, a computing device, but otherwise might not necessarily be readily perceivable by humans (e.g., if in a digital format). Likewise, in the context of the present patent application, digital content provided to a user in a form so that the user is able to readily perceive the underlying content itself (e.g., content presented in a form consumable by a human, such as hearing audio, feeling tactile sensations and/or seeing images, as examples) is referred to, with respect to the user, as “consuming” digital content, “consumption” of digital content, “consumable” digital content and/or similar terms. For one or more embodiments, an electronic document and/or an electronic file may comprise a Web page of code (e.g., computer instructions) in a markup language executed or to be executed by a computing and/or networking device, for example. In another embodiment, an electronic document and/or electronic file may comprise a portion and/or a region of a Web page. However, claimed subject matter is not intended to be limited in these respects.

Also, for one or more embodiments, an electronic document and/or electronic file may comprise a number of components. As previously indicated, in the context of the present patent application, a component is physical, but is not necessarily tangible. As an example, components with reference to an electronic document and/or electronic file, in one or more embodiments, may comprise text, for example, in the form of physical signals and/or physical states (e.g., capable of being physically displayed). Typically, memory states, for example, comprise tangible components, whereas physical signals are not necessarily tangible, although signals may become (e.g., be made) tangible, such as if appearing on a tangible display, for example, as is not uncommon. Also, for one or more embodiments, components with reference to an electronic document and/or electronic file may comprise a graphical object, such as, for example, an image, such as a digital image, and/or sub-objects, including attributes thereof, which, again, comprise physical signals and/or physical states (e.g., capable of being tangibly displayed). In an embodiment, digital content may comprise, for example, text, images, audio, video, and/or other types of electronic documents and/or electronic files, including portions thereof, for example.

Also, in the context of the present patent application, the term “parameters” (e.g., one or more parameters), “values” (e.g., one or more values), “symbols” (e.g., one or more symbols) “bits” (e.g., one or more bits), “elements” (e.g., one or more elements), “characters” (e.g., one or more characters), “numbers” (e.g., one or more numbers), “numerals” (e.g., one or more numerals) or “measurements” (e.g., one or more measurements) refer to material descriptive of a collection of signals, such as in one or more electronic documents and/or electronic files, and exist in the form of physical signals and/or physical states, such as memory states. For example, one or more parameters, values, symbols, bits, elements, characters, numbers, numerals or measurements, such as referring to one or more aspects of an electronic document and/or an electronic file comprising an image, may include, as examples, time of day at which an image was captured, latitude and longitude of an image capture device, such as a camera, for example, etc. In another example, one or more parameters, values, symbols, bits, elements, characters, numbers, numerals or measurements, relevant to digital content, such as digital content comprising a technical article, as an example, may include one or more authors, for example. Claimed subject matter is intended to embrace meaningful, descriptive parameters, values, symbols, bits, elements, characters, numbers, numerals or measurements in any format, so long as the one or more parameters, values, symbols, bits, elements, characters, numbers, numerals or measurements comprise physical signals and/or states, which may include, as parameter, value, symbol bits, elements, characters, numbers, numerals or measurements examples, collection name (e.g., electronic file and/or electronic document identifier name), technique of creation, purpose of creation, time and date of creation, logical path if stored, coding formats (e.g., type of computer instructions, such as a markup language) and/or standards and/or specifications used so as to be protocol compliant (e.g., meaning substantially compliant and/or substantially compatible) for one or more uses, and so forth.

Signal packet communications and/or signal frame communications, also referred to as signal packet transmissions and/or signal frame transmissions (or merely “signal packets” or “signal frames”), may be communicated between nodes of a network, where a node may comprise one or more network devices and/or one or more computing devices, for example. As an illustrative example, but without limitation, a node may comprise one or more sites employing a local network address, such as in a local network address space. Likewise, a device, such as a network device and/or a computing device, may be associated with that node. It is also noted that in the context of this patent application, the term “transmission” is intended as another term for a type of signal communication that may occur in any one of a variety of situations. Thus, it is not intended to imply a particular directionality of communication and/or a particular initiating end of a communication path for the “transmission” communication. For example, the mere use of the term in and of itself is not intended, in the context of the present patent application, to have particular implications with respect to the one or more signals being communicated, such as, for example, whether the signals are being communicated “to” a particular device, whether the signals are being communicated “from” a particular device, and/or regarding which end of a communication path may be initiating communication, such as, for example, in a “push type” of signal transfer or in a “pull type” of signal transfer. In the context of the present patent application, push and/or pull type signal transfers are distinguished by which end of a communications path initiates signal transfer.

Thus, a signal packet and/or frame may, as an example, be communicated via a communication channel and/or a communication path, such as comprising a portion of the Internet and/or the Web, from a site via an access node coupled to the Internet or vice-versa. Likewise, a signal packet and/or frame may be forwarded via network nodes to a target site coupled to a local network, for example. A signal packet and/or frame communicated via the Internet and/or the Web, for example, may be routed via a path, such as either being “pushed” or “pulled,” comprising one or more gateways, servers, etc. that may, for example, route a signal packet and/or frame, such as, for example, substantially in accordance with a target and/or destination address and availability of a network path of network nodes to the target and/or destination address. Although the Internet and/or the Web comprise a network of interoperable networks, not all of those interoperable networks are necessarily available and/or accessible to the public. According to an embodiment, a signal packet and/or frame may comprise all or a portion of a “message” transmitted between devices. In an implementation, a message may comprise signals and/or states expressing content to be delivered to a recipient device. For example, a message may at least in part comprise a physical signal in a transmission medium that is modulated by content that is to be stored in a non-transitory storage medium at a recipient device, and subsequently processed.

In the context of the particular patent application, a network protocol, such as for communicating between devices of a network, may be characterized, at least in part, substantially in accordance with a layered description, such as the so-called Open Systems Interconnection (OSI) seven layer type of approach and/or description. A network computing and/or communications protocol (also referred to as a network protocol) refers to a set of signaling conventions, such as for communication transmissions, for example, as may take place between and/or among devices in a network. In the context of the present patent application, the term “between” and/or similar terms are understood to include “among” if appropriate for the particular usage and vice-versa. Likewise, in the context of the present patent application, the terms “compatible with,” “comply with” and/or similar terms are understood to respectively include substantial compatibility and/or substantial compliance.

A network protocol, such as protocols characterized substantially in accordance with the aforementioned OSI description, has several layers. These layers are referred to as a network stack. Various types of communications (e.g., transmissions), such as network communications, may occur across various layers. A lowest level layer in a network stack, such as the so-called physical layer, may characterize how symbols (e.g., bits and/or bytes) are communicated as one or more signals (and/or signal samples) via a physical medium (e.g., twisted pair copper wire, coaxial cable, fiber optic cable, wireless air interface, combinations thereof, etc.). Progressing to higher-level layers in a network protocol stack, additional operations and/or features may be available via engaging in communications that are substantially compatible and/or substantially compliant with a particular network protocol at these higher-level layers. For example, higher-level layers of a network protocol may, for example, affect device permissions, user permissions, etc.

In one example embodiment, as shown in FIG. 4, a system embodiment may comprise a local network (e.g., device 804 and medium 840) and/or another type of network, such as a computing and/or communications network. For purposes of illustration, therefore, FIG. 4 shows an embodiment 800 of a system that may be employed to implement either type or both types of networks. Network 808 may comprise one or more network connections, links, processes, services, applications, and/or resources to facilitate and/or support communications, such as an exchange of communication signals, for example, between a computing device, such as 802, and another computing device, such as 806, which may, for example, comprise one or more client computing devices and/or one or more server computing device. By way of example, but not limitation, network 808 may comprise wireless and/or wired communication links, telephone and/or telecommunications systems, Wi-Fi networks, Wi-MAX networks, the Internet, a local area network (LAN), a wide area network (WAN), or any combinations thereof.

Example devices in FIG. 4 may comprise features, for example, of a client computing device and/or a server computing device, in an embodiment. It is further noted that the term computing device, in general, whether employed as a client and/or as a server, or otherwise, refers at least to a processor and a memory connected by a communication bus. A “processor” and/or “processing circuit” for example, is understood to connote a specific structure such as a central processing unit (CPU), digital signal processor (DSP), graphics processing unit (GPU) and/or neural network processing unit (NPU), or a combination thereof, of a computing device which may include a control unit and an execution unit. In an aspect, a processor and/or processing circuit may comprise a device that fetches, interprets and executes instructions to process input signals to provide output signals. As such, in the context of the present patent application at least, this is understood to refer to sufficient structure within the meaning of 35 USC § 112 (f) so that it is specifically intended that 35 USC § 112 (f) not be implicated by use of the term “computing device,” “processor,” “processing unit,” “processing circuit” and/or similar terms; however, if it is determined, for some reason not immediately apparent, that the foregoing understanding cannot stand and that 35 USC § 112 (f), therefore, necessarily is implicated by the use of the term “computing device” and/or similar terms, then, it is intended, pursuant to that statutory section, that corresponding structure, material and/or acts for performing one or more functions be understood and be interpreted to be described at least in FIG. 1 through FIG. 3 and in the text associated with the foregoing figure(s) of the present patent application.

Referring now to FIG. 4, in an embodiment, first and third devices 802 and 806 may be capable of rendering a graphical user interface (GUI) for a network device and/or a computing device, for example, so that a user-operator may engage in system use. Device 804 may potentially serve a similar function in this illustration. Likewise, in FIG. 4, computing device 802 (‘first device’ in figure) may interface with computing device 804 (‘second device’ in figure), which may, for example, also comprise features of a client computing device and/or a server computing device, in an embodiment. Processor (e.g., processing device) 820 and memory 822, which may comprise primary memory 824 and secondary memory 826, may communicate by way of a communication bus 815, for example. The term “computing device,” in the context of the present patent application, refers to a system and/or a device, such as a computing apparatus, that includes a capability to process (e.g., perform computations) and/or store digital content, such as electronic files, electronic documents, measurements, text, images, video, audio, etc. in the form of signals and/or states. Thus, a computing device, in the context of the present patent application, may comprise hardware, software, firmware, or any combination thereof (other than software per se). Computing device 804, as depicted in FIG. 4, is merely one example, and claimed subject matter is not limited in scope to this particular example. FIG. 4 may further comprise a communication interface 830 which may comprise circuitry and/or devices to facilitate transmission of messages between second device 804 and first device 802 and/or third device 806 in a physical transmission medium over network 808 using one or more network communication techniques identified herein, for example. In a particular implementation, communication interface 830 may comprise a transmitter device including devices and/or circuitry to modulate a physical signal in physical transmission medium according to a particular communication format based, at least in part, on a message that is intended for receipt by one or more recipient devices. Similarly, communication interface 830 may comprise a receiver device comprising devices and/or circuitry demodulate a physical signal in a physical transmission medium to, at least in part, recover at least a portion of a message used to modulate the physical signal according to a particular communication format. In a particular implementation, communication interface may comprise a transceiver device having circuitry to implement a receiver device and transmitter device.

For one or more embodiments, a device, such as a computing device and/or networking device, may comprise, for example, any of a wide range of digital electronic devices, including, but not limited to, desktop and/or notebook computers, high-definition televisions, digital versatile disc (DVD) and/or other optical disc players and/or recorders, game consoles, satellite television receivers, cellular telephones, tablet devices, wearable devices, personal digital assistants, mobile audio and/or video playback and/or recording devices, Internet of Things (IoT) type devices, or any combination of the foregoing. Further, unless specifically stated otherwise, a process as described, such as with reference to flow diagrams and/or otherwise, may also be executed and/or affected, in whole or in part, by a computing device and/or a network device. A device, such as a computing device and/or network device, may vary in terms of capabilities and/or features. Claimed subject matter is intended to cover a wide range of potential variations. For example, a device may include a numeric keypad and/or other display of limited functionality, such as a monochrome liquid crystal display (LCD) for displaying text, for example. In contrast, however, as another example, a web-enabled device may include a physical and/or a virtual keyboard, mass storage, one or more accelerometers, one or more gyroscopes, GNSS receiver and/or other location-identifying type capability, and/or a display with a higher degree of functionality, such as a touch-sensitive color 5D or 3D display, for example.

In FIG. 4, computing device 802 may provide one or more sources of executable computer instructions in the form physical states and/or signals (e.g., stored in memory states), for example. Computing device 802 may communicate with computing device 804 by way of a network connection, such as via network 808, for example. As previously mentioned, a connection, while physical, may not necessarily be tangible. Although computing device 804 of FIG. 4 shows various tangible, physical components, claimed subject matter is not limited to a computing devices having only these tangible components as other implementations and/or embodiments may include alternative arrangements that may comprise additional tangible components or fewer tangible components, for example, that function differently while achieving similar results. Rather, examples are provided merely as illustrations. It is not intended that claimed subject matter be limited in scope to illustrative examples.

Memory 822 may comprise any non-transitory storage mechanism. Memory 822 may comprise, for example, primary memory 824 and secondary memory 826, additional memory circuits, mechanisms, or combinations thereof may be used. Memory 822 may comprise, for example, random access memory, read only memory, etc., such as in the form of one or more storage devices and/or systems, such as, for example, a disk drive including an optical disc drive, a tape drive, a solid-state memory drive, etc., just to name a few examples.

Memory 822 may be utilized to store a program of executable computer instructions. For example, processor 820 may fetch executable instructions from memory and proceed to execute the fetched instructions. Memory 822 may also comprise a memory controller for accessing device readable-medium 840 that may carry and/or make accessible digital content, which may include code, and/or instructions, for example, executable by processor 820 and/or some other device, such as a controller, as one example, capable of executing computer instructions, for example. Under direction of processor 820, a non-transitory memory, such as memory cells storing physical states (e.g., memory states), comprising, for example, a program of executable computer instructions, may be executed by processor 820 and able to generate signals to be communicated via a network, for example, as previously described. Generated signals may also be stored in memory, also previously suggested.

Memory 822 may store electronic files and/or electronic documents, such as relating to one or more users, and may also comprise a computer-readable medium that may carry and/or make accessible content, including code and/or instructions, for example, executable by processor 820 and/or some other device, such as a controller, as one example, capable of executing computer instructions, for example. As previously mentioned, the term electronic file and/or the term electronic document are used throughout this document to refer to a set of stored memory states and/or a set of physical signals associated in a manner so as to thereby form an electronic file and/or an electronic document. That is, it is not meant to implicitly reference a particular syntax, format and/or approach used, for example, with respect to a set of associated memory states and/or a set of associated physical signals. It is further noted an association of memory states, for example, may be in a logical sense and not necessarily in a tangible, physical sense. Thus, although signal and/or state components of an electronic file and/or electronic document, are to be associated logically, storage thereof, for example, may reside in one or more different places in a tangible, physical memory, in an embodiment.

Algorithmic descriptions and/or symbolic representations are examples of techniques used by those of ordinary skill in the signal processing and/or related arts to convey the substance of their work to others skilled in the art. An algorithm is, in the context of the present patent application, and generally, is considered to be a self-consistent sequence of operations and/or similar signal processing leading to a desired result. In the context of the present patent application, operations and/or processing involve physical manipulation of physical quantities. Typically, although not necessarily, such quantities may take the form of electrical and/or magnetic signals and/or states capable of being stored, transferred, combined, compared, processed and/or otherwise manipulated, for example, as electronic signals and/or states making up components of various forms of digital content, such as signal measurements, text, images, video, audio, etc.

It has proven convenient at times, principally for reasons of common usage, to refer to such physical signals and/or physical states as bits, values, elements, parameters, symbols, characters, terms, samples, observations, weights, numbers, numerals, measurements, content and/or the like. It should be understood, however, that all of these and/or similar terms are to be associated with appropriate physical quantities and are merely convenient labels. Unless specifically stated otherwise, as apparent from the preceding discussion, it is appreciated that throughout this specification discussions utilizing terms such as “processing,” “computing,” “calculating,” “determining”, “establishing”, “obtaining”, “identifying”, “selecting”, “generating”, and/or the like may refer to actions and/or processes of a specific apparatus, such as a special purpose computer and/or a similar special purpose computing and/or network device. In the context of this specification, therefore, a special purpose computer and/or a similar special purpose computing and/or network device is capable of processing, manipulating and/or transforming signals and/or states, typically in the form of physical electronic and/or magnetic quantities, within memories, registers, and/or other storage devices, processing devices, and/or display devices of the special purpose computer and/or similar special purpose computing and/or network device. In the context of this particular patent application, as mentioned, the term “specific apparatus” therefore includes a general purpose computing and/or network device, such as a general purpose computer, once it is programmed to perform particular functions, such as pursuant to program software instructions.

In some circumstances, operation of a memory device, such as a change in state from a binary one to a binary zero or vice-versa, for example, may comprise a transformation, such as a physical transformation. With particular types of memory devices, such a physical transformation may comprise a physical transformation of an article to a different state or thing. For example, but without limitation, for some types of memory devices, a change in state may involve an accumulation and/or storage of charge or a release of stored charge. Likewise, in other memory devices, a change of state may comprise a physical change, such as a transformation in magnetic orientation. Likewise, a physical change may comprise a transformation in molecular structure, such as from crystalline form to amorphous form or vice-versa. In still other memory devices, a change in physical state may involve quantum mechanical phenomena, such as, superposition, entanglement, and/or the like, which may involve quantum bits (qubits), for example. The foregoing is not intended to be an exhaustive list of all examples in which a change in state from a binary one to a binary zero or vice-versa in a memory device may comprise a transformation, such as a physical, but non-transitory, transformation. Rather, the foregoing is intended as illustrative examples.

Referring again to FIG. 4, processor 820 may comprise one or more circuits, such as digital circuits, to perform at least a portion of a computing procedure and/or process. By way of example, but not limitation, processor 820 may comprise one or more processors, such as controllers, microprocessors, microcontrollers, application specific integrated circuits, digital signal processors (DSPs), graphics processing units (GPUs), neural network processing units (NPUs), programmable logic devices, field programmable gate arrays, the like, or any combination thereof. In various implementations and/or embodiments, processor 820 may perform signal processing, typically substantially in accordance with fetched executable computer instructions, such as to manipulate signals and/or states, to construct signals and/or states, etc., with signals and/or states generated in such a manner to be communicated and/or stored in memory, for example.

FIG. 4 also illustrates device 804 as including a component 832 operable with input/output devices, for example, so that signals and/or states may be appropriately communicated between devices, such as device 804 and an input device and/or device 804 and an output device. A user may make use of an input device, such as a computer mouse, stylus, track ball, keyboard, and/or any other similar device capable of receiving user actions and/or motions as input signals. Likewise, for a device having speech to text capability, a user may speak to a device to generate input signals. A user may make use of an output device, such as a display, a printer, etc., and/or any other device capable of providing signals and/or generating stimuli for a user, such as visual stimuli, audio stimuli and/or other similar stimuli.

In the preceding description, various aspects of claimed subject matter have been described. For purposes of explanation, specifics, such as amounts, systems and/or configurations, as examples, were set forth. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all modifications and/or changes as fall within claimed subject matter.

What is claimed is:

1. A method comprising:
computing for two or more design options of two or more of a plurality of design decisions for at least one layer of a neural network of a processor design, function values based, at least in part, on an expression of sample weights applicable to nodes and/or edges in the neural network and coefficients associated with respective design options; and
determining an objective function based, at least in part, on a combination of computed function values associated with the design decisions.

2. The method of claim 1, wherein the combination of computed function values comprises first computed function values associated with a design decision for bit width and second computed function values associated with a design decision for a random pruning approach, and wherein the objective function is to optimize the at least one layer with respect to the design decisions for bit width and the random pruning approach concurrently.

3. The method of claim 1, wherein the computed function values are associated with at least a design decision for bit width conditioned on a design decision for a random pruning approach.

4. The method of claim 1, wherein the computed values are associated with at least a design decision for a random pruning approach conditioned on a design decision for bit width.

5. The method of claim 1, wherein the objective function is determined for iterations of computations of the function values, and the method further comprises:
updating coefficients to compute the function values based, at least in part, on the objective function determined based, at least in part, on a first iteration of the function values, the updated coefficients to be applied in computation of the function values in a second, subsequent iteration of the function values.

6. The method of claim 5, wherein the updated coefficients are determined based, at least in part, according to a Markov chain Monte Carlo sampling of coefficients applied in computation of function values in a preceding iteration of function values.

7. The method of claim 6, wherein the updated coefficients are further determined based, at least in part, on a gradient operation applied to iterations of the objective function.

8. The method of claim 1, wherein coefficients associated with design options of at least a first design decision of the two or more of the plurality of design decisions are categorically distributed.

9. The method of claim 1, wherein the combination of computed function values associated with the design decisions comprises a sum of the computed function values.

10. The method of claim 1, wherein determining the objective function further comprises determining the objective function subject to one or more processing constraints.

11. The method of claim 10, wherein at least one of the one or more processing constraints comprises an availability of memory.

12. The method of claim 10, wherein at least one of the one or more processing constraints is represented by a first numerical value and at least one attribute of the processor design is associated with a second numerical value, and wherein the objective function is determined at, least in part, on an expected absolute value of a difference between the first and second numerical values.

13. A computing device comprising:
one or more memory devices to store computer-readable instructions; and
one or more processors to execute the stored computer-readable instructions to:
compute for two or more design options of two or more of a plurality of design decisions for at least one layer of a neural network of a processor design, function values based, at least in part, on an expression of sample weights applicable to nodes and/or edges in the neural network and coefficients associated with respective design options; and
determine an objective function based, at least in part, on a combination of computed function values associated with the design decisions.

14. The computing device of claim 13, wherein the combination of computed function values to comprise first computed function values associated with a design decision for bit width and second computed function values associated with a design decision for a random pruning approach, and wherein the objective function is to optimize the at least one layer with respect to the design decisions for bit width and the random pruning approach concurrently.

15. The computing device of claim 13, wherein the computed function values to be associated with at least a design decision for bit width conditioned on a design decision for a random pruning approach.

16. The computing device of claim 13, wherein the computed values to be associated with at least a design decision for a random pruning approach conditioned on a design decision for bit width.

17. The computing device of claim 13, wherein the objective function to be determined subject to one or more processing constraints.

18. An article comprising:
a non-transitory storage medium comprising computer-readable instructions stored thereon which are executable by one or more processors of a computing device to:
computing for two or more design options of two or more of a plurality of design decisions for at least one layer of a neural network of a processor design, function values based, at least in part, on an expression of sample weights applicable to nodes and/or edges in the neural network and coefficients associated with respective design options; and
determine an objective function based, at least in part, on a combination of computed function values associated with the design decisions.

19. The article of claim 18, wherein the combination of computed function values to comprise first computed function values associated with a design decision for bit width and second computed function values associated with a design decision for a random pruning approach, and wherein the objective function is to optimize the at least one layer with respect to the design decisions for bit width and the random pruning approach concurrently.

20. The computing device of claim 18, wherein the computed function values to be associated with at least a design decision for bit width conditioned on a design decision for the random pruning approach.
